(19) United States
(12) Patent Application Publication
(10) Pub. No.: US 2011/0260200 A1
(43) Pub. Date: Oct. 27, 2011

(54) METHOD OF FABRICATING NON-METAL LED SUBSTRATE AND NON-METAL LED SUBSTRATE AND METHOD OF FABRICATING LED DEVICE USING THE NON-METAL LED SUBSTRATE AND LED DEVICE WITH THE NON-METAL LED SUBSTRATE

(76) Inventor: Yi-Chang Chen, Xinbei City (TW)

(21) Appl. No.: 13/039,896

(22) Filed: Mar. 3, 2011

(30) Foreign Application Priority Data
Apr. 23, 2010 (TW) 099112764

(51) Int. Cl. H01L 33/62; H05K 1/09; G03F 7/20; C25D 5/54; B32B 3/10

(52) U.S. Cl. 257/99; 438/26; 205/159; 156/150; 428/137; 430/314; 174/257; 257/E33.066

(57) ABSTRACT

The present invention discloses a method of fabricating non-metal substrate having steps of (a) providing a non-metal board having two opposite first and second surfaces; (b) drilling at least one second through hole through the non-metal board; (c) electroplating copper on outsides of non-metal board and an inside of each of at least one second through hole to form copper films outside of the non-metal board and at least one solid copper pole in corresponding to the at lest one second through hole; and (d) patterning the copper films to form line pattern. The non-metal substrate has high thermal conductivity and the solid copper poles therein are integrated with the line pattern formed outside thereof, so the connection strength among the die pad, solid copper poles and heat conduction pad is good.

### BACKGROUND OF THE INVENTION

1. Field of the Invention

The present invention relates to the field of a fabricating method of an LED substrate, and more particularly to a method of fabricating non-metal LED substrate.

2. Description of Related Art

In general, the LED substrate may be made of metal material or ceramic material. LTCC, HTCC, DBC and DPC are four fabricating procedures for the ceramic substrate. The DBC or DPC substrate has better thermal conductivity than others. Since the DBC substrate has a combination of a ceramic board and a copper board, a high temperature environment (1065° C.˜1085° C.) is required to mount the copper board on the ceramic board. However, executing the DPC procedure only requires 250° C.˜350° C. temperature environment. Therefore, the DPC substrate not only has good thermal conductivity, but also uses the simple and low cost fabricating procedure.

The fabricating procedure of the DPC substrate has following steps:
a. cleaning a ceramic board;
b. forming a copper film by a vacuum sputtering deposition;
c. etching the copper film to form line pattern on the ceramic board; and
d. increasing a thickness of the line pattern by electroplating copper and eletcroless plating copper techniques.

In general, a line width of line pattern of the DPC substrate is about 10 μm to 50 μm, so a size of the DPC substrate is efficiently decreased and has good thermal conductivity.

To increase better thermal conductivity of the DPC substrate, an enhanced DPC procedure is proposed. With reference to FIGS. 9 A to 9E, the enhanced DPC procedure has following steps of:

a. providing a ceramic board 51;

b. drilling multiple electric conduction through holes 511 and one heat conduction through hole 512;

c. providing a copper pole 60 corresponding to the heat conduction through hole 512;

d. inserting the copper pole 60 into the heat conduction through hole 512;

e. sputtering copper on the ceramic board to form copper films 513 on outsides of the ceramic board 51 and insides the electric conduction through holes 511 by the Sputtering Deposition technique; and

f. etching the copper films 513 outside of the ceramic board 51 to form a die pad pattern 52 and a wire bonding pad pattern 53 on a top outside, and a heat conduction pad pattern 54 and a solder pad pattern 55. The copper films inside the electric conduction through hole 511 are connected to the wire bonding pad pattern 53 and solder pad pattern 55. The copper pole 60 is connected to the die pad 52 pattern and the heat conduction pad pattern 54.

When an LED chip is mounted on the die pad pattern, heat generated from the LED chip is conduct to the heat conduction pad pattern through the copper pole. Since the thermal conductivity of the copper pole is better than that of the ceramic board, the enhanced DPC substrate has better thermal conductivity. However, the enhanced DPC procedure still has some drawbacks, such as unstable connection strength among the die pad pattern, the copper pole and the heat conduction pad pattern, and high fabricating cost for forming accurate diameter of the heat conduction through hole, and alignment between the copper pole and the heat conductive through hole.

In addition, to successfully form copper films inside the through hole, the minimum diameter of the through hole will be 0.5 mm for the ceramic board with 1 mm thickness. Therefore, the drilling step to drill smaller the electric conduction through hole and the heat conduction through hole is high cost for small scale LED substrate.

### SUMMARY OF THE INVENTION

The main objective of the present invention is to provide a method of fabricating non-metal LED substrate and the non-metal LED substrate.

The method of fabricating non-metal substrate having steps of (a) providing a non-metal board having two opposite first and second surfaces; (b) drilling at least one second through hole through the non-metal board; (c) electroplating copper on outsides of non-metal board and an inside of each of at least one second through hole to form copper films outside of the non-metal board and at least one solid copper pole in corresponding to the at lest one second through hole; and (d) patterning the copper films to form line pattern. The non-metal substrate has high thermal conductivity and the solid copper poles therein are integrated with the line pattern formed outside thereof, so the connection strength among the die pad, solid copper poles and heat conduction pad is good.

Other objectives, advantages and novel features of the invention will become more apparent from the following detailed description when taken in conjunction with the accompanying drawings.

### BRIEF DESCRIPTION OF THE DRAWINGS

FIGS. 1A to 1E are cross sectional views of an LED device during executing a first embodiment of a method of fabricating non-metal LED device in accordance with the present invention;

FIG. 2 is a top plan view of the LED device in FIG. 1D;

FIGS. 3A to 3E are cross sectional views of an LED device during executing a second embodiment of a method of fabricating non-metal LED device in accordance with the present invention;

FIG. 4 is a top plan view of the LED device in FIG. 3D;

FIG. 5 is a bottom plan view of the LED device in FIG. 3D;

FIG. 6 is a top plan view of another LED device in accordance with the present invention;

FIG. 7 is a top plan view of another LED device in accordance with the present invention;

FIG. 8A is a cross sectional view of the LED device in FIG. 1E mounted on a heat sink device;

FIG. 8B is a cross sectional view of the LED device in FIG. 3E mounted on a printed circuit board; and

FIGS. 9A to 9E are cross sectional views of an enhanced DPC substrate during executing an enhanced DPC procedure.

### DETAILED DESCRIPTION OF THE PREFERRED EMBODIMENT

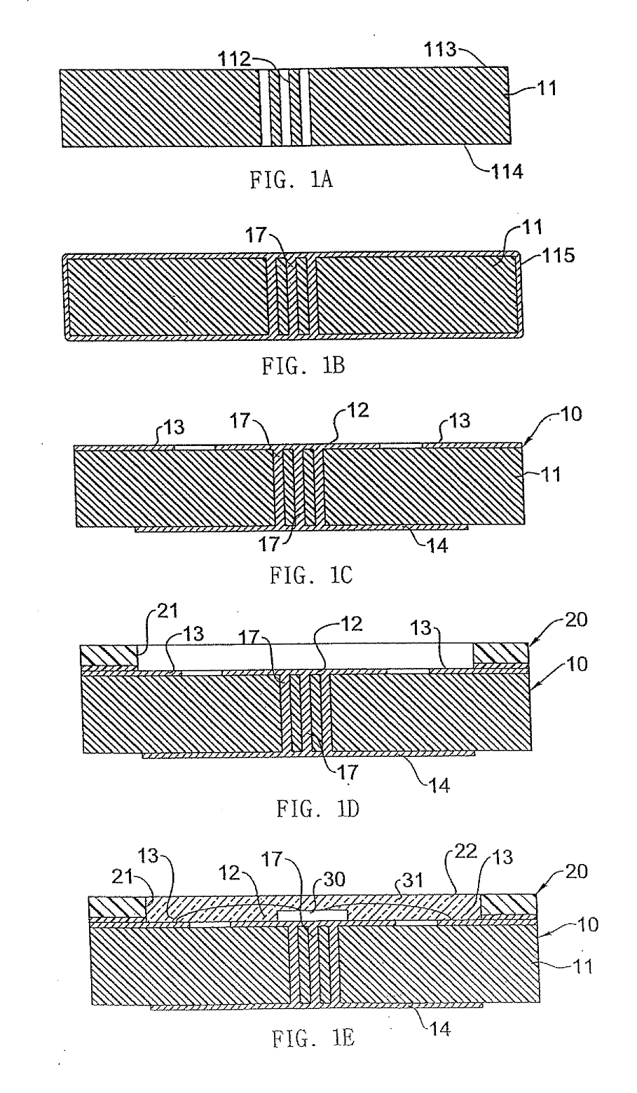

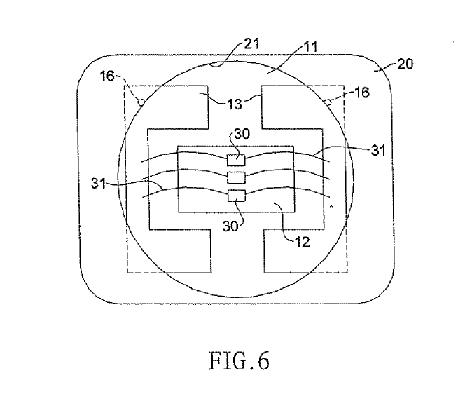

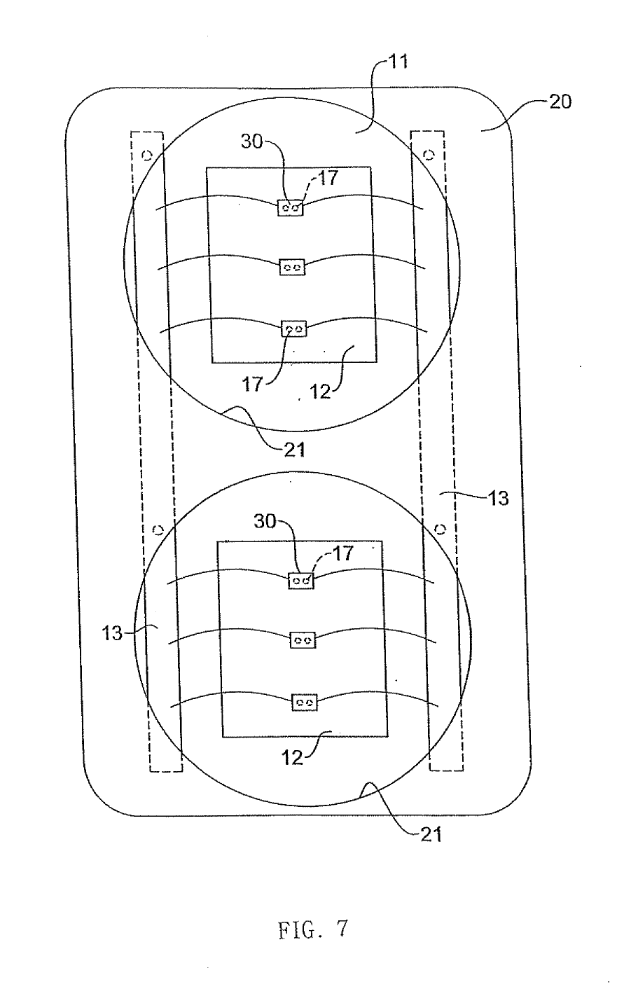

With reference to FIGS. 1A to 1E, a first embodiment of a method of fabricating an LED device in accordance with the present invention has following steps. The LED device is directly mounted on a heat sink device 40 as shown in FIG. 5A.

The first embodiment of the fabricating method has following steps.

(a) providing a non-metal board 11; wherein the non-metal board 10 may be a ceramic board or a silicon board and a thickness of non-metal board 11 may be 0.3 mm to 2 mm;

(b) drilling at least one second through hole 112 through the non-metal board 11 by a laser drilling technique or other drilling hole technique and a diameter of each of the at least one second through hole 112 is about 0.02 mm to 0.15 mm;

(c) electroplating copper on outsides of non-metal board 11 and an inside of each of at least one second through hole 112 to form copper films 115 outside of the non-metal board 11 and at least one solid copper pole 17 in corresponding to the at lest one second through hole 112;

(d) patterning the copper films 115 to form a line pattern having at least one die pad 12 and multiple wire bonding pads 13 on a first surface of the non-metal board 11, and a heat conduction pad 14 on a second surface opposite to the first surface so the at least one copper pole 17 for heat conduction are integrated with the die pad 12 and heat conduction pad 14; wherein a first embodiment of a non-metal substrate 11 is fabricated when the patterning step is ended and the non-metal substrate 11 has one die pad 12, one heat conduction pad 15 and two wire bonding pads 13;

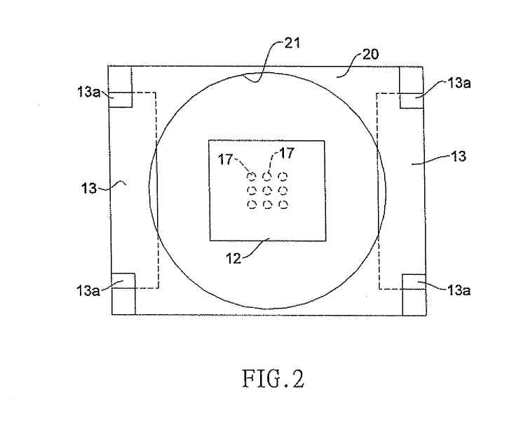

(e) preparing a frame 20 with at lest one opening 21, wherein the least one opening 21 of the frame 20 aligns to the at least one die pad 12 and parts of the wire bonding pads 13, and then is securely mounted on the first surface of the non-metal board 11 by pressing technique to expose the at least one die pad 12 and parts of the wire bonding pads 13; wherein with further reference to FIG. 2, the frame 20 has one opening 21 to align one die pad 12 and two inner parts of the wire bonding pads 13, four corners of the frame 20 are cut to expose other four outer parts of the wire bonding pad 13 used as external terminals 13a of the LED device, and may be a glass fiber board or an anodized aluminum board;

(f) preparing at least one LED chip 30 and mounting to the corresponding die pad 12;

(g) wire bonding the LED chip 13 and the inner parts of the wire bonding pads 12; and

(h) pouring liquid glue into the at least one opening 21 of the frame 20 and then forming an encapsulation 22 to seal the at least one LED chip 30 therein after the liquid glue is solid.

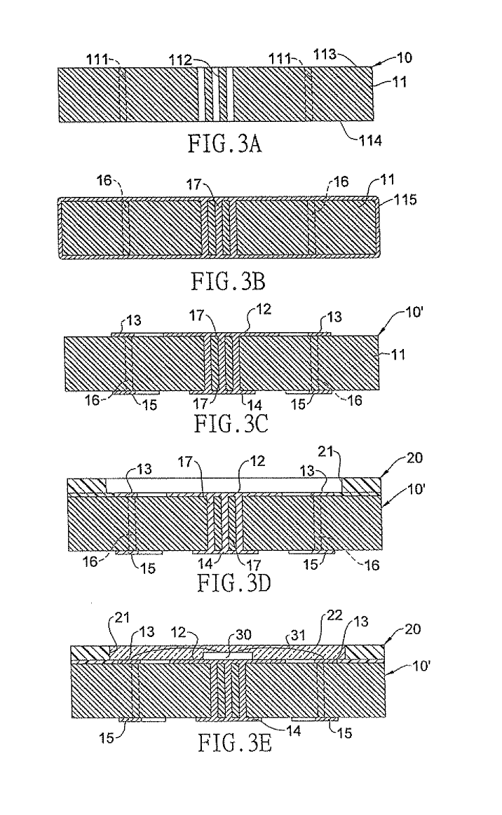

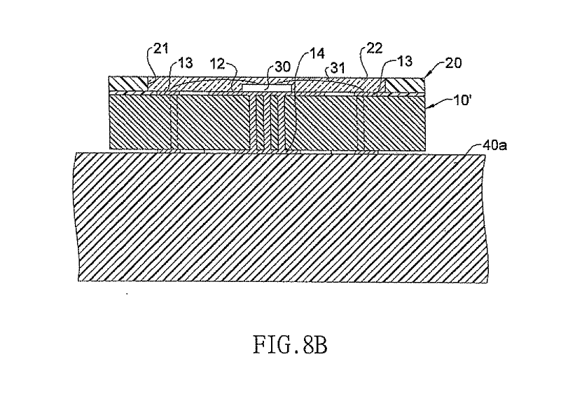

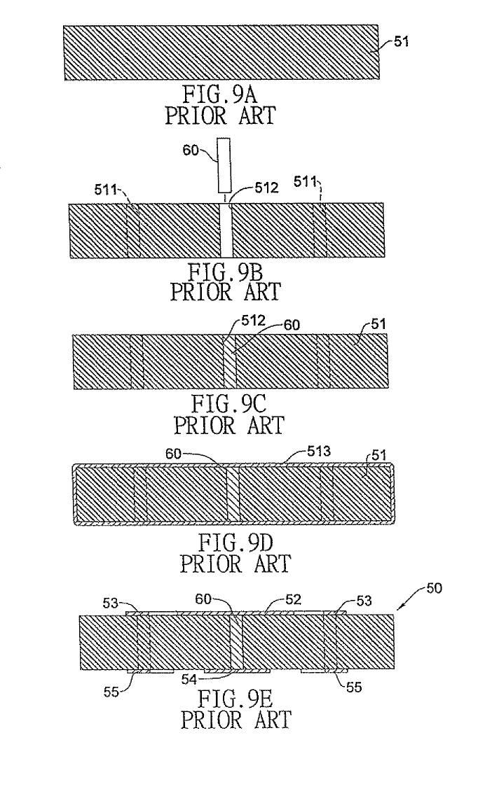

With further reference to FIGS. 3A to 3E, a second embodiment of a method of fabricating an LED device in accordance with the present invention has following steps. The LED device of this embodiment is directly mounted on a printed circuit board (hereinafter PCB) as shown in FIG. 8B.

The second embodiment of the fabricating method has following steps.

(a) providing a non-metal board 11; wherein the non-metal board 11 may be a ceramic board or a silicon board and a thickness of non-metal board 11 may be 0.3 mm to 2 mm;

(b) drilling multiple first through hole 111 and at least one second through hole 112 by a laser drilling technique or other drilling hole technique and a diameter of each of the at least one first or second through hole 111, 112 is about 0.02 mm to 0.15 mm;

(c) electroplating copper on outsides of the non-metal board 11 and an inside of each of the first through hole 111 and at least one second through hole 112 to form copper films 115 outside of the non-metal board 11, multiple first solid copper poles 16 for electric conduction in corresponding first through hole 111, and at least one second solid copper pole 17 for heat conduction in corresponding second through hole 112;

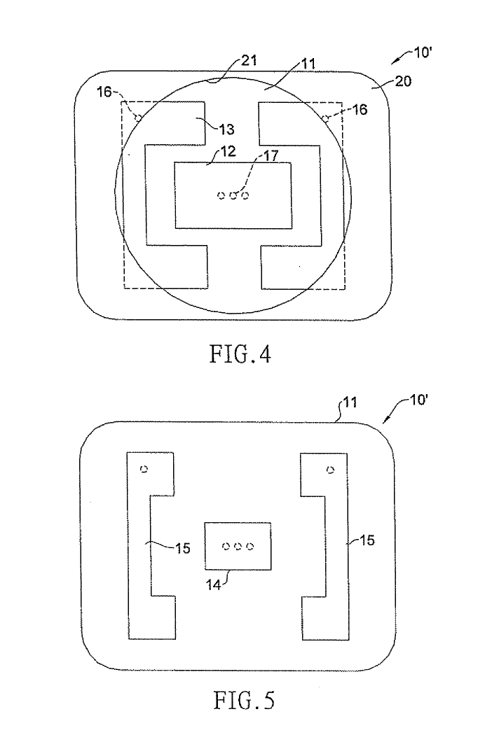

(d) patterning the copper films 115 to form at least one die pad 12 and multiple wire bonding pads 13 on a first surface of the non-metal board 11, and a heat conduction pad 14 and multiple soldering pads 15 on a second surface opposite to the first surface so the solid copper poles 16 for electric conduction are integrated with the wire bonding pads 13 and the soldering pads 15, and the at least one copper pole 17 for heat conduction are integrated with the die pad 12 and heat conduction pad 14, wherein a second embodiment of a non-metal substrate 10a is fabricated when the patterning step is ended and the non-metal substrate 10a has one die pad 12, one heat conduction pad 14, two wire bonding pads 13 and two soldering pads 15 used as external terminals of the LED device, as shown in FIGS. 4 and 5;

(e) preparing a frame 20 with at lest one opening 21, wherein the least one opening 21 of the frame 20 aligns to the at least one die pad 12 and parts of the wire bonding pads 13, and then is securely mounted on the first surface of the non-metal board 11 by pressing technique to expose the at least one die pad 12 and parts of the wire bonding pads 13; wherein with further reference to FIG. 4, the frame 20 has one opening 21 to align one die pad 12 and two inner parts of the wire bonding pads 13 and may be a glass fiber board or an anodized aluminum board;

(f) preparing at least one LED chip 30 and mounting to the corresponding die pad 12;

(g) wire bonding the LED chip 30 and the inner parts of the wire bonding pads 13; and

(h) pouring liquid glue into the at least one opening 21 of the frame 20 and then forming an encapsulation 22 to seal the at least one LED chip 30 therein after the liquid glue is solid. Since the frame 20 stops the liquid glue overflowing outside of the frame 20, the step of pouring liquid is quite simple.

In the step of electroplating copper the non-metal board, the non-metal board is previously processed by detailing, acid cleaning and activation etc. processes, and then processed by Eletcroless Plating Copper or Eletcroless Plating Nickel. After completing Eletcroless Plating Copper or Eletcroless Plating Nickel process, the non-metal board is put into copper electroplating solution to electroplate the non-metal board. After completing the step of electroplating copper, the solid copper poles are respectively formed in the corresponding through holes.

In the step of patterning copper films, a photoresist film is coated on the outsides of the copper films and then patterned to partially cover the copper films. Therefore, parts of the copper films uncovered by the patterned photoresist film are further etched, and then the patterned photoresist film is removed to expose line pattern including the die pad, wire bonding pads, heat conduction pad and/or soldering pads. In addition, parts of line pattern are coated by silicone oil. Then, a tin solder layer is formed on other parts of the line pattern non-coated by the silicon oil. Besides, the line pattern may be sequentially formed an electroplated nickel and an electroplated silver, or sequentially formed an electroplated nickel and an electroplated gold before coating silicone oil as so to form multilayer of line pattern with high electric conduction. A thickness of the electroplated nickel is over 3 μm, a thickness of the electroplated silver is over 1 um and a thickness of the electroplated gold is over 0.025 μm.

With reference to FIGS. 1E and 2, a first embodiment of the non-metal substrate 10 in accordance with the present invention has a non-metal board 11 and a frame 20.

The non-metal board 11 may be a ceramic board or a silicon board, and has two opposite first and second surfaces, at least one solid copper pole 17 for heat conduction, and a line pattern. The line pattern has a die pad 12, multiple wire bonding pads 13 and a heat conduction pad 14. The die pad 12 and wire bonding pads 13 are formed on the first surface and the heat conduction pad 14 is formed on the second surface. The solid copper pole 17 is formed through the non-metal board 11 and integrated with the die pad 12 and the heat conduction pad 14 since the die pad 12, the heat conduction pad 14 and the solid pole 17 are formed in the same process. Numbers of the solid copper poles 17 are determined according to thermal conduction efficiency.

The frame 20 is securely mounted on the first surface of the non-metal board 11 and has one opening 21 and four cutting. The opening 21 of the frame 20 is corresponding to the die pad 12 and inner parts of the two wire bonding pads 13 and four cuttings are corresponding to four corners of the non-metal board 11 to expose four outer parts of the wire bonding pads used as the soldering terminals 13a of the LED device.

With reference to FIGS. 3E, 4 and 5, a second embodiment of the non-metal substrate 10a in accordance with the present invention is similar to the first embodiment thereof. The non-metal board 11 further has multiple solid copper poles 16 for electric conduction and multiple soldering pads 15 formed on the second surface of the non-metal board 11 and corresponding to the wire bonding pads 13. The solid copper poles 16 for electric conduction are formed through the non-metal board 11 and integrated with the wire bonding pads 13 and the soldering pads 15 since the solid copper poles 16 for electric conduction, the wire bonding pad 13 and soldering pads 15 are formed in the same process.

With reference to FIG. 1E, a first embodiment of the LED device in accordance with the present invention has a non-metal substrate 10 shown in FIG. 1D, at least one LED chip 30, wires 31 and at least one encapsulation 22.

The at least one LED chip 30 is mounted on the corresponding die pad 12 and wires 31 are respectively bonded between the LED chip 30 and the inner parts of the wire bonding pads 13 by wire bonding process. The encapsulation 22 formed inside the opening 21 of the frame 20 so as to seal the LED chip 30 and wires 31 therein. With further reference to FIG. 8A, the heat conduction pad 14 of the non-metal substrate 10 is directly mounted on the heat sink device 40.

With reference to FIG. 3E, a second embodiment of the LED device in accordance with the present invention has a non-metal substrate 10a shown in FIG. 3D, at least one LED chip 30, wires 31 and at least one encapsulation 22.

The at least one LED chip 30 is mounted on the corresponding die pad 12 and wires 31 are respectively bonded between the LED chip 30 and the inner parts of the wire bonding pads 13 by wire bonding process. The encapsulation 22 formed inside the opening 21 of the frame 20 so as to seal the LED chip 30 and wires 31 therein. With further reference to FIG. 8B, the heat conduction pad 14 of the non-metal substrate is directly mounted on the PCB 40a and the soldering pads 15 are soldered to the PCB 40a. The heat from the LED chip 30 is conducted to the PCB 40a through the die pad 12, the solid copper poles 17 for heat conduction and the heat conduction pad 14.

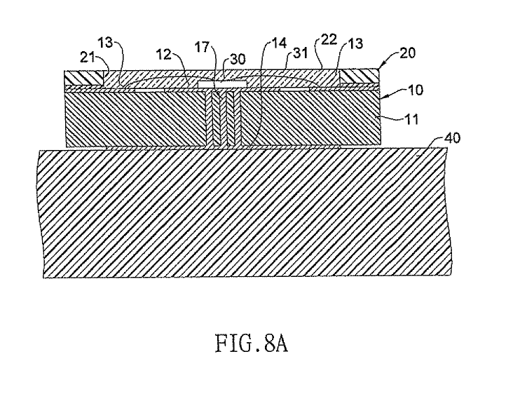

With reference to FIG. 7, a third embodiment of the LED device has a non-metal substrate 10b, multiple LED chips 30, wires 31 and two encapsulations (not shown). The non-metal board 11 of the non-metal substrate 10b has two die pads 12, each of which corresponds to multiple solid copper poles 17 for heat conduction. The frame 20 has two openings 21 respectively corresponding to die pads 12. Three LED chips 30 are mounted on one die pad 12 and wire bonding to the corresponding inner parts of the wire bonding pads 13.

Based on the foregoing description, the non-metal substrate has high thermal conductivity and the solid copper poles therein are integrated with the line pattern formed outside thereof, so the connection strength among the die pad, solid copper poles and heat conduction pad is good. In addition, the fabricating method save alignment step and does not need to previously make the copper pole so as to provide low fabricating cost.

Even though numerous characteristics and advantages of the present invention have been set forth in the foregoing description, together with details of the structure and function of the invention, the disclosure is illustrative only. Changes may be made in detail, especially in matters of shape, size, and arrangement of parts within the principles of the invention to the full extent indicated by the broad general meaning of the terms in which the appended claims are expressed.

What is claimed is:

1. A method of fabricating non-metal LED substrate comprising steps of
(a) providing a non-metal board having two opposite first and second surfaces;
(b) drilling at least one second through hole through the non-metal board;
(c) electroplating copper on outsides of non-metal board and an inside of each of at least one second through hole to form copper films outside of the non-metal board and at least one solid copper pole in corresponding to the at lest one second through hole; and
(d) patterning the copper films to form line pattern having at least one die pad and multiple wire bonding pads on the first surface of the non-metal board, and a heat conduction pad on the second surface of the non-metal board.

2. The fabricating method as claimed in claim 1, wherein
in the drilling step, multiple first through holes are further drilled through the non-metal board;
in the electroplating step, multiple solid poles for electric conduction are respectively formed inside the first through holes; and
in the patterning step, the line pattern further has multiple soldering pads on the second surface of the non-metal board, wherein the solid copper poles for electric conduction are integrated with the wire bonding pads and the soldering pads.

3. The fabricating method as claimed in claim 1, after the step of patterning further comprising:
(e) preparing a frame with at lest one opening, wherein the least one opening of the frame aligns to the at least one die pad and parts of the wire bonding pads, and then is securely mounted on the first surface of the non-metal board to expose the at least one die pad and parts of the wire bonding pads.

4. The fabricating method as claimed in claim 2, after the step of patterning further comprising:
(e) preparing a frame with at lest one opening, wherein the least one opening of the frame aligns to the at least one die pad and parts of the wire bonding pads, and then is securely mounted on the first surface of the non-metal board to expose the at least one die pad and parts of the wire bonding pads.

5. The fabricating method as claimed in claim 4, wherein the frame is a glass fiber board or an anodized aluminum board and mounted on the first surface by pressing technique.

6. The fabricating method as claimed in claim 5, wherein in the step of electroplating, the non-metal board is previously processed by defatting, acid cleaning and activation processes, and further processed by Eletcroless Plating Copper or Eletcroless Plating Nickel, and then putting into copper electroplating solution to electroplate the non-metal board.

7. The fabricating method as claimed in claim 6, wherein the step of patterning further comprises acts of:
coating a photoresist film on the outsides of the copper films;
patterning the photoresist film to partially cover the copper films so that parts of the copper films are uncovered by the patterned photoresist film;
etching the parts of the copper films uncovered by the patterned photoresist film;
removing the patterned photoresist film to expose a line pattern having the die pad, the wire bonding pads, the heat conduction pad and the soldering pads;
coating silicone oil on parts of the line pattern; and
forming a tin solder layer on other parts of the line pattern non-coated by the silicon oil.

8. The fabricating method as claimed in claim 6, wherein the step of patterning further comprises acts of:
coating a photoresist film on the outsides of the copper films;
patterning the photoresist film to partially cover the copper films so that parts of the copper films are uncovered by the patterned photoresist film;
etching the parts of the copper films uncovered by the patterned photoresist film;
removing the patterned photoresist film to expose a line pattern having the die pad, the wire bonding pads, the heat conduction pad and the soldering pads;
forming sequentially an electroplated nickel and an electroplated silver on the line pattern; and
coating silicon oil on parts of the line pattern.

9. The fabricating method as claimed in claim 6, wherein the step of patterning further comprises acts of:
coating a photoresist film on the outsides of the copper films;
patterning the photoresist film to partially cover the copper films so that parts of the copper films are uncovered by the patterned photoresist film;
etching the parts of the copper films uncovered by the patterned photoresist film;
removing the patterned photoresist film to expose a line pattern having the die pad, the wire bonding pads, the heat conduction pad and the soldering pads;
forming sequentially an electroplated nickel and an electroplated gold on the line pattern; and
coating silicon oil on parts of the line pattern.

10. The fabricating method as claimed in claim 2, wherein
a thickness of the non-metal board is 0.3 to 2 mm; and
a diameter of each of the first and second through holes is over 0.02 mm.

11. The fabricating method as claimed in claim 8, wherein
a thickness of the non-metal board is 0.3 to 2 mm;
a diameter of each of the first and second through holes is 0.02 mm to 0.15 mm;
a thickness of the electroplated nickel is over 3 μm; and
a thickness of the electroplated silver is over 1 μm.

12. The fabricating method as claimed in claim 9, wherein
a thickness of the non-metal board is 0.3 to 2 mm;
a diameter of each of the first and second through holes is 0.02 mm to 0.15 mm;
a thickness of the electroplated nickel is over 3 μm; and
a thickness of the electroplated gold is over 0.025 μm.

13. The fabricating method as claimed in claim 3, wherein the non-metal board is a ceramic board or a silicon board.

14. The fabricating method as claimed in claim 4, wherein the non-metal board is a ceramic board or a silicon board.

15. An non-metal LED substrate, comprising:
a non-metal board having two opposite first and second surfaces, at least one solid copper pole for heat conduction and a line pattern, wherein the line pattern has a die pad, multiple wire bonding pads and a heat conduction pad, wherein the die pad and wire bonding pads are formed on the first surface and the heat conduction pad is formed on the second surface; the at least one solid copper it pole for heat conduction is formed through the non-metal board and integrated with the die pad and the heat conduction pad; and
a frame securely mounted on the first surface of the non-metal board and having one opening a, wherein the opening of the frame is corresponding to the die pad and inner parts of the wire bonding pads.

16. The non-metal LED substrate as claimed in claim 15, the frame further having multiple cuttings corresponding to outer parts of wire bonding pads to expose the outer parts of the wire bonding pads used as solder terminals.

17. The non-metal LED substrate as claimed in claim 15, the non-metal board further comprising:
multiple soldering pads formed on the second surface of the non-metal board; and
multiple solid copper poles for electric conduction form through the non-metal board and integrated with the wire bonding pads and the soldering pads.

18. The non-metal LED substrate as claimed in claim 15, wherein the frame is a glass fiber board or an anodized aluminum board and mounted on the first surface by pressing technique.

19. The non-metal LED substrate as claimed in claim 16, wherein the frame is a glass fiber board or an anodized aluminum board and mounted on the first surface by pressing technique.

20. The non-metal LED substrate as claimed in claim 17, wherein the frame is a glass fiber board or an anodized aluminum board and mounted on the first surface by pressing technique.

21. The non-metal LED substrate as claimed in claim 15, wherein the at least one die pad, the line pattern is made of copper.

22. The non-metal LED substrate as claimed in claim 15, wherein parts of the line pattern is coated silicon oil and the tin solder layer.

23. The non-metal LED substrate as claimed in claim 18, wherein line pattern is further sequentially formed an electroplated nickel and an electroplated silver.

24. The non-metal LED substrate as claimed in claim 19, wherein line pattern is further sequentially formed an electroplated nickel and an electroplated silver.

25. The non-metal LED substrate as claimed in claim 20, wherein line pattern is further sequentially formed an electroplated nickel and an electroplated silver.

26. The non-metal LED substrate as claimed in claim 18, wherein line pattern is further sequentially formed an electroplated nickel and an electroplated gold.

27. The non-metal LED substrate as claimed in claim 19, wherein line pattern is further sequentially formed an electroplated nickel and an electroplated gold.

28. The non-metal LED substrate as claimed in claim 20, wherein line pattern is further sequentially formed an electroplated nickel and an electroplated gold.

29. The non-metal LED substrate as claimed in claim 23, wherein
a thickness of the non-metal board is 0.3 to 2 mm;
a diameter of each of the solid copper poles for heat conduction and electric conduction is 0.02 mm to 0.15 mm;
a thickness of the electroplated nickel is over 3 μm; and
a thickness of the electroplated silver is over 1 μm.

30. The non-metal LED substrate as claimed in claim 24, wherein
a thickness of the non-metal board is 0.3 to 2 mm;
a diameter of each of the solid copper poles for heat conduction and electric conduction is 0.02 mm to 0.15 mm;
a thickness of the electroplated nickel is over 3 μm; and
a thickness of the electroplated silver is over 1 μm.

31. The non-metal LED substrate as claimed in claim 25, wherein
a thickness of the non-metal board is 0.3 to 2 mm;
a diameter of each of the solid copper poles for heat conduction and electric conduction is 0.02 mm to 0.15 mm;
a thickness of the electroplated nickel is over 3 μm; and
a thickness of the electroplated silver is over 1 μm.

32. The non-metal LED substrate as claimed in claim 26, wherein
a thickness of the non-metal board is 0.3 to 2 mm;
a diameter of each of the solid copper poles for heat conduction and electric conduction is 0.02 mm to 0.15 mm;
a thickness of the electroplated nickel is over 3 μm; and
a thickness of the electroplated gold is over 0.025 μm.

33. The non-metal LED substrate as claimed in claim 27, wherein
a thickness of the non-metal board is 0.3 to 2 mm;
a diameter of each of the solid copper poles for heat conduction and electric conduction is 0.02 mm to 0.15 mm;
a thickness of the electroplated nickel is over 3 μm; and
a thickness of the electroplated gold is over 0.025 μm.

34. The non-metal LED substrate as claimed in claim 28, wherein
a thickness of the non-metal board is 0.3 to 2 mm;
a diameter of each of the solid copper poles for heat conduction and electric conduction is 0.02 mm to 0.15 mm;
a thickness of the electroplated nickel is over 3 μm; and
a thickness of the electroplated gold is over 0.025 μm.

35. A method of fabricating LED device comprising steps of
(a) providing a non-metal board having two opposite first and second surfaces;
(b) drilling at least one second through hole through the non-metal board;
(c) electroplating copper on outsides of non-metal board and an inside of each of at least one second through hole to form copper films outside of the non-metal board and at least one solid copper pole in corresponding to the at lest one second through hole;
(d) patterning the copper films to form line pattern having at least one die pad and multiple wire bonding pads on the first surface of the non-metal board, and a heat conduction pad on the second surface of the non-metal board;
(f) preparing at least one LED chip and mounting to the corresponding die pad;
(g) wire bonding the LED chip and the inner parts of the wire bonding pads; and
(h) pouring liquid glue into the at least one opening of the frame and then forming an encapsulation to seal the at least one LED chip therein after the liquid glue is solid.

36. The fabricating method as claimed in claim 35, wherein
in the drilling step, multiple first through holes are further drilled through the non-metal board;
in the electroplating step, multiple solid poles for electric conduction are respectively formed inside the first through holes; and
in the patterning step, the line pattern further has multiple soldering pads on the second surface of the non-metal board, wherein the solid copper poles for electric conduction are integrated with the wire bonding pads and the soldering pads.

37. The fabricating method as claimed in claim 35, after the step of patterning further comprising:
(e) preparing a frame with at lest one opening, wherein the least one opening of the frame aligns to the at least one die pad and parts of the wire bonding pads, and then is securely mounted on the first surface of the non-metal board to expose the at least one die pad and parts of the wire bonding pads.

38. The fabricating method as claimed in claim 36, after the step of patterning further comprising:
(e) preparing a frame with at lest one opening, wherein the least one opening of the frame aligns to the at least one die pad and parts of the wire bonding pads, and then is securely mounted on the first surface of the non-metal board to expose the at least one die pad and parts of the wire bonding pads.

39. The fabricating method as claimed in claim 38, wherein the frame is a glass fiber board or an anodized aluminum board and mounted on the first surface by pressing technique.

40. The fabricating method as claimed in claim 39, wherein in the step of electroplating, the non-metal board is previously processed by defatting, acid cleaning and activation processes, and further processed by Eletcroless Plating Copper or Eletcroless Plating Nickel, and then putting into copper electroplating solution to electroplate the non-metal board.

41. The fabricating method as claimed in claim 40, wherein the step of patterning further comprises acts of:
coating a photoresist film on the outsides of the copper films;
patterning the photoresist film to partially cover the copper films so that parts of the copper films are uncovered by the patterned photoresist film;
etching the parts of the copper films uncovered by the patterned photoresist film;
removing the patterned photoresist film to expose a line pattern having the die pad, the wire bonding pads, the heat conduction pad and the soldering pads;
coating silicone oil on parts of the line pattern; and
forming a tin solder layer on other parts of the line pattern non-coated by the silicon oil.

42. The fabricating method as claimed in claim 40, wherein the step of patterning further comprises acts of:
coating a photoresist film on the outsides of the copper films;
patterning the photoresist film to partially cover the copper films so that parts of the copper films are uncovered by the patterned photoresist film;
etching the parts of the copper films uncovered by the patterned photoresist film;
removing the patterned photoresist film to expose a line pattern having the die pad, the wire bonding pads, the heat conduction pad and the soldering pads;
forming sequentially an electroplated nickel and an electroplated silver on the line pattern; and
coating silicon oil on parts of the line pattern.

43. The fabricating method as claimed in claim 40, wherein the step of patterning further comprises acts of:
coating a photoresist film on the outsides of the copper films;
patterning the photoresist film to partially cover the copper films so that parts of the copper films are uncovered by the patterned photoresist film;
etching the parts of the copper films uncovered by the patterned photoresist film;
removing the patterned photoresist film to expose a line pattern having the die pad, the wire bonding pads, the heat conduction pad and the soldering pads;
forming sequentially an electroplated nickel and an electroplated gold on the line pattern; and
coating silicon oil on parts of the line pattern.

44. The fabricating method as claimed in claim 36, wherein
a thickness of the non-metal board is 0.3 to 2 mm; and
a diameter of each of the first and second through holes is 0.02 to 0.15 mm.

45. The fabricating method as claimed in claim 42, wherein
a thickness of the non-metal board is 0.3 to 2 mm;
a diameter of each of the first and second through holes is 0.02 mm to 0.15 mm;
a thickness of the electroplated nickel is over 3 μm; and
a thickness of the electroplated silver is over 1 μm.

46. The fabricating method as claimed in claim 43, wherein
a thickness of the non-metal board is 0.3 to 2 mm;
a diameter of each of the first and second through holes is 0.02 to 0.15 mm;
a thickness of the electroplated nickel is over 3 μm; and
a thickness of the electroplated gold is over 0.025 μm.

47. The fabricating method as claimed in claim 37, wherein the non-metal board is a ceramic board or a silicon board.

48. The fabricating method as claimed in claim 38, wherein the non-metal board is a ceramic board or a silicon board.

49. An LED device, comprising:
a non-metal board having two opposite first and second surfaces, at least one solid copper pole for heat conduction and a line pattern, wherein the line pattern has a die pad, multiple wire bonding pads and a heat conduction pad, wherein the die pad and wire bonding pads are aimed on the first surface and the heat conduction pad is formed on the second surface; the at least one solid copper pole for heat conduction is formed through the non-metal board and integrated with the die pad and the heat conduction pad;
a frame securely mounted on the first surface of the non-metal board and having one opening a, wherein the opening of the frame is corresponding to the die pad and inner parts of the wire bonding pads;
at least one LED chip mounted on the corresponding die pad;
multiple wires bonding between the at least one LED chip and the corresponding die pad; and
at least one encapsulation mounted inside the corresponding opening of the frame and sealing the LED chips and wires therein.

50. The LED device as claimed in claim 49, the frame further having multiple cuttings corresponding to outer parts of wire bonding pads to expose the outer parts of the wire bonding pads used as solder terminals.

51. The LED device as claimed in claim 49, the non-metal board further comprising:
multiple soldering pads formed on the second surface of the non-metal board; and
multiple solid copper poles for electric conduction form through the non-metal board and integrated with the wire bonding pads and the soldering pads.

52. The LED device as claimed in claim 49, wherein the frame is a glass fiber board or an anodized aluminum board and mounted on the first surface by pressing technique.

53. The LED device as claimed in claim 50, wherein the frame is a glass fiber board or an anodized aluminum board and mounted on the first surface by pressing technique.

54. The LED device as claimed in claim 51, wherein the frame is a glass fiber board or an anodized aluminum board and mounted on the first surface by pressing technique.

55. The LED device as claimed in claim 49, wherein the at least one die pad, the line pattern is made of copper.

56. The LED device claimed in claim 49, wherein parts of the line pattern is coated silicon oil and the tin solder layer.

57. The LED device as claimed in claim 52, wherein line pattern is further sequentially formed an electroplated nickel and an electroplated silver.

58. The LED device as claimed in claim 53, wherein line pattern is further sequentially formed an electroplated nickel and an electroplated silver.

59. The LED device as claimed in claim 54, wherein line pattern is further sequentially formed an electroplated nickel and an electroplated silver.

60. The LED device as claimed in claim 52, wherein line pattern is further sequentially formed an electroplated nickel and an electroplated gold.

61. The LED device as claimed in claim 53, wherein line pattern is further sequentially formed an electroplated nickel and an electroplated gold.

62. The LED device as claimed in claim 54, wherein line pattern is further sequentially fowled an electroplated nickel and an electroplated gold.

63. The LED device as claimed in claim 57, wherein
a thickness of the non-metal board is 0.3 to 2 mm;
a diameter of each of the solid copper poles for heat conduction and electric conduction is 0.02 to 0.15 mm;
a thickness of the electroplated nickel is over 3 μm; and
a thickness of the electroplated silver is over 1 μm.

64. The LED device as claimed in claim 58, wherein
a thickness of the non-metal board is 0.3 to 2 mm;
a diameter of each of the solid copper poles for heat conduction and electric conduction is 0.02 to 0.15 mm;
a thickness of the electroplated nickel is over 3 μm; and
a thickness of the electroplated silver is over 1 μm.

65. The LED device as claimed in claim 59, wherein
a thickness of the non-metal board is 0.3 to 2 mm;
a diameter of each of the solid copper poles for heat conduction and electric conduction is 0.02 to 0.15 mm;
a thickness of the electroplated nickel is over 3 μm; and
a thickness of the electroplated silver is over 1 μm.

66. The LED device as claimed in claim 60, wherein
a thickness of the non-metal board is 0.3 to 2 mm;
a diameter of each of the solid copper poles for heat conduction and electric conduction is 0.02 mm to 0.15 mm;
a thickness of the electroplated nickel is over 3 μm; and
a thickness of the electroplated gold is over 0.025 μm.

67. The LED device as claimed in claim 61, wherein
a thickness of the non-metal board is 0.3 to 2 mm;
a diameter of each of the solid copper poles for heat conduction and electric conduction is 0.02 mm to 0.15 mm;
a thickness of the electroplated nickel is over 3 μm; and
a thickness of the electroplated gold is over 0.025 μm.

68. The LED device as claimed in claim 62, wherein
a thickness of the non-metal board is 0.3 to 2 mm;
a diameter of each of the solid copper poles for heat conduction and electric conduction is 0.02 mm to 0.15 mm;
a thickness of the electroplated nickel is over 3 μm; and
a thickness of the electroplated gold is over 0.025 μm.
